(19) United States
(12) Patent Application Publication
(10) Pub. No.: US 2016/0321135 A1
(43) Pub. Date: Nov. 3, 2016

(54) MEMORY SYSTEMS HAVING REDUCED MEMORY CHANNEL TRAFFIC AND METHODS FOR OPERATING THE SAME

(71) Applicant: Samsung Electronics Co., Ltd., Suwon-si (KR)

(72) Inventors: Amit BERMAN, Ramat Gan (IL); Uri BEITLER, Ramat Gan (IL); Jun Jin KONG, Yongin-si (KR)

(21) Appl. No.: 14/699,810

(22) Filed: Apr. 29, 2015

(51) Int. Cl. G06F 11/10; H03M 13/00; H03M 13/05

(52) U.S. Cl. CPC G06F 11/1044; H03M 13/05; H03M 13/611

(57) ABSTRACT

A memory device controller includes an error correction processor and a compression processor. The error correction processor is configured to obtain error location information for page data received from a source memory block over a memory channel. The compression processor is configured to compress the obtained error location information, and to output the compressed error location information to a target memory block without the page data over the same memory channel.

### BACKGROUND

In conventional solid state devices (SSDs), data is stored in units referred to as pages. A page unit is finite in size and can only be written to when empty. Consequently, to write to a page that already contains data, the page must first be erased. Each page belongs to a group of pages referred to as a memory block. While data is written in units of pages, data is erased in blocks.

Within an SSD, a SSD controller utilizes a Flash Translation Layer (FTL), which coordinates communication between the NAND flash and the host system. Utilizing the FTL, the SSD implements a logical to physical mapping system called Logical Block Addressing (LBA). By utilizing the FTL and LBA, physical NAND writes need not correspond directly to the space requested by the host system. Accordingly, instead of erasing the memory block including the particular page requested by the host system, and overwriting a piece of old data in the particular page, the SSD writes the new data to a next available page, and then marks the old data as invalid. Unfortunately, this manner of storing data results in fragmented storage of valid data among the physical space in the SSD.

As an SSD is filled with data, fewer free memory blocks are readily available. To free memory space for storing additional data in advance, the SSD performs what is referred to as garbage collection. During a garbage collection operation, the SSD consolidates valid data, and erases memory blocks to reclaim free memory space in the SSD.

Garbage collection operations frequently include copy-back operations. A copy-back operation is a page data copy operation in which page data is copied from a source page to a target page.

Conventional SSD configurations, however, result in a relatively large amount of bus traffic during garbage collection processes including copy-back operations.

### SUMMARY

One or more example embodiments provide methods for reducing data traffic over solid state device (SSD) channels. According to at least one example embodiment, data that is read and transferred from a source NAND device to a device controller is concurrently and/or simultaneously loaded from the source NAND device to a target NAND device on the same channel as the source NAND device. Transmission of page data to the device controller is required due to error handling (e.g., page program operation address errors, etc.). However, the response from the device controller to the target NAND device includes error locations, but not the read page data.

Example embodiments may also enable the use of read-for-copy-back commands, which are not employed in conventional SSDs because of additive write errors.

At least some example embodiments provide a more efficient traffic garbage collection method that may reduce garbage collection traffic on SSD channels. At least some example embodiments utilize superblock parallelism, and when page data is output from a NAND device to another NAND device that shares the same channel and to the memory device controller in parallel.

At least one example embodiment provides a memory device controller. According to at least this example embodiment, the memory device includes: an error correction processor configured to obtain error location information for page data received from a source memory block over a memory channel; and a compression processor configured to compress the obtained error location information, and to output the compressed error location information to a target memory block without the received page data over the same memory channel.

At least one other example embodiment provides a storage device. According to at least this example embodiment, the storage device includes: a source non-volatile memory device connected to a memory channel, the source non-volatile memory device including a source memory block; and a memory device controller configured to communicate with the source non-volatile memory device via the memory channel. The memory device controller includes: an error correction processor configured to obtain error location information for page data received from the source memory block over the memory channel; and a compression processor configured to compress the obtained error location information, and output the compressed error location information to a target memory block without the page data over the same memory channel.

The compression processor may be configured to output only the compressed error location information to the target memory block. The error correction processor may be further configured to perform error correction coding on the received page data to obtain the error location information for the page data, the error location information including locations of errors in the received page data.

The source memory block and the target memory block may be located at a same non-volatile memory device connected to the memory channel.

According to at least some example embodiments, the received page data may be valid page data read from the source memory block during a garbage collection operation.

According to at least some example embodiments, the received page data may be on-chip buffered program (OBP) data, and the compressed error location information may be buffered prior to being output to the target memory block.

The source memory block and the target memory block may be located at a same non-volatile memory device connected to the memory channel.

At least one other example embodiment provides a storage device. According to at least this example embodiment, the storage device includes: a first non-volatile memory device connected to a memory channel, the first non-volatile memory device including a plurality of memory blocks and a page buffer. The first non-volatile memory device is configured to: buffer page data read from a source memory block; correct errors in the buffered page data in response to receiving error location information from a memory device controller via the memory channel, and without receiving the page data from the memory device controller; and write the error corrected page data to a target memory block among the plurality of memory blocks of the first non-volatile memory device.

At least one of the source and the target memory blocks may be in the form of a three-dimensional memory array. The three dimensional memory array includes a plurality of memory cells, each of the plurality of memory cells including a charge trap layer. The first non-volatile memory device may be a NAND device.

The first non-volatile memory device may be configured to correct errors in the buffered page data in response to receiving only the compressed error location information from the memory device controller.

The first non-volatile memory device may further include the source memory block.

The page data may be one of on-chip buffered program (OBP) data and valid page data read from the source memory block during a garbage collection operation.

At least one other example embodiment provides a storage system. According to at least this example embodiment, the storage device includes a storage device including a plurality of non-volatile memory devices and a memory device controller, the plurality of non-volatile memory devices and the memory device controller being connected via a memory channel. The storage device is configured to: read out page data from a first memory block at a first of the plurality of non-volatile memory devices to the memory device controller; and transfer the page data from the first memory block at the first of the plurality of non-volatile memory devices to a buffer at a second of the plurality of non-volatile memory devices concurrently with the read out of the page data to the memory device controller.

The memory device controller may include: an error correction processor configured to obtain error location information for the page data read out from the first of the plurality of non-volatile memory devices; and a compression processor configured to compress the obtained error location information, and output the compressed error location information to the second of the plurality of non-volatile memory devices without the page data via the memory channel.

The second of the plurality of non-volatile memory devices may be configured to: buffer the page data received from the first memory block at the first of the plurality of non-volatile memory devices; correct errors in the buffered page data in response to receiving the error location information from the memory device controller via the memory channel, and without receiving the read out page data from the memory device controller; and write the error corrected page data to a second memory block at the second of the plurality of memory blocks.

### BRIEF DESCRIPTION OF THE DRAWINGS

Example embodiments will become more appreciable through the description of the drawings in which:

FIG. 1 is a block diagram schematically illustrating a storage system according to an example embodiment.

FIG. 2A is a block diagram illustrating an example embodiment of a portion of the storage device shown in FIG. 1 in more detail.

FIG. 2B is a block diagram illustrating an example embodiment of the NAND device 202 in more detail.

FIG. 3 is a flow chart illustrating a method for performing garbage collection on a memory block, according to an example embodiment.

FIG. 4 is a block diagram illustrating another example embodiment of a portion of the storage device shown in FIG. 1 in more detail.

FIG. 5 is a flow chart illustrating a method for performing an OBP operation, according to an example embodiment.

FIG. 6 is a block diagram illustrating a memory card system including a storage device according to an example embodiment.

FIG. 7 is a block diagram illustrating a Universal Flash Storage (UFS) system in which a storage device according to an example embodiment may be implemented.

FIG. 8 is a block diagram illustrating an electronic device in which a storage device according to an example embodiment may be implemented.

FIG. 9 is a block diagram schematically illustrating a computing system including a storage system according to an example embodiment.

FIG. 10 is a block diagram schematically illustrating a handheld terminal including a storage device according to an example embodiment.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. The use of similar or identical reference numbers in the various drawings is intended to indicate the presence of a similar or identical element or feature.

### DETAILED DESCRIPTION

Example embodiments will now be described more fully with reference to the accompanying drawings. Many alternate forms may be embodied and example embodiments should not be construed as limited to example embodiments set forth herein. In the drawings, like reference numerals refer to like elements.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless specifically stated otherwise, or as is apparent from the discussion, terms such as “processing” or “computing” or “calculating” or “determining” or “displaying” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Specific details are provided in the following description to provide a thorough understanding of example embodiments. However, it will be understood by one of ordinary skill in the art that example embodiments may be practiced without these specific details. For example, systems may be shown in block diagrams so as not to obscure the example embodiments in unnecessary detail. In other instances, well-known processes, structures and techniques may be shown without unnecessary detail in order to avoid obscuring example embodiments.

In the following description, illustrative embodiments will be described with reference to acts and symbolic representations of operations (e.g., in the form of flow charts, flow diagrams, data flow diagrams, structure diagrams, block diagrams, etc.) that may be implemented as program modules or functional processes include routines, programs, objects, components, data structures, etc., that perform particular tasks or implement particular abstract data types and may be implemented using existing hardware in existing electronic systems (e.g., non-volatile memories, universal flash memories, universal flash memory controllers, non-volatile memories and memory controllers, storage systems, digital point-and-shoot cameras, personal digital assistants (PDAs), smartphones, tablet personal computers (PCs), laptop computers, etc.). Such existing hardware may include one or more Central Processing Units (CPUs), digital signal processors (DSPs), application-specific-integrated-circuits (ASICs), System-on-Chip (SoC), field programmable gate arrays (FPGAs) computers or the like.

Further, according to one or more example embodiments, hosts, storage devices, device controllers, interfaces (host and/or device), error correction coding (ECC) circuits and/or processors, compression processors, etc., may be (or include) hardware, firmware, hardware executing software or any combination thereof. Such hardware may include one or more CPUs, SOC devices, DSPs, ASICs, FPGAs, computers, or the like configured as special purpose machines to perform the functions described herein as well as any other well-known functions of these elements. In at least some cases, CPUs, SOCs, DSPs, ASICs and FPGAs may generally be referred to as processing circuits, processors and/or microprocessors.

Although a flow chart may describe operations as a sequential process, many of the operations may be performed in parallel, concurrently or simultaneously. In addition, the order of the operations may be re-arranged. A process may be terminated when its operations are completed, but may also have additional steps not included in the figure. A process may correspond to a method, function, procedure, subroutine, subprogram, etc. When a process corresponds to a function, its termination may correspond to a return of the function to the calling function or the main function.

As disclosed herein, the term “storage medium”, “computer readable storage medium” or “non-transitory computer readable storage medium,” may represent one or more devices for storing data, including read only memory (ROM), random access memory (RAM), magnetic RAM, core memory, magnetic disk storage mediums, optical storage mediums, flash memory devices and/or other tangible machine readable mediums for storing information. The term “computer-readable medium” may include, but is not limited to, portable or fixed storage devices, optical storage devices, and various other mediums capable of storing, containing or carrying instruction(s) and/or data.

Furthermore, example embodiments may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a computer readable storage medium. When implemented in software, processor(s), processing circuit(s), or processing unit(s) may be programmed to perform the necessary tasks, thereby being transformed into special purpose processor(s) or computer(s).

A code segment may represent a procedure, function, subprogram, program, routine, subroutine, module, software package, class, or any combination of instructions, data structures or program statements. A code segment may be coupled to another code segment or a hardware circuit by passing and/or receiving information, data, arguments, parameters or memory contents. Information, arguments, parameters, data, etc. may be passed, forwarded, or transmitted via any suitable means including memory sharing, message passing, token passing, network transmission, etc.

As data is written to a non-volatile memory, (e.g., flash-based SSDs, flash memory, etc.), fewer free memory blocks are readily available for storing data received from a host. To free memory space for storing additional data in advance, the SSD performs what is referred to as garbage collection. During a garbage collection operation, the SSD consolidates valid data, and erases memory blocks to reclaim free memory space in the SSD.

Garbage collection operations frequently include copy-back operations. A copy-back operation is a page data copy operation in which page data is copied from a source page to a target page. However, conventional SSD configurations and garbage collection processes result in a relatively large amount of traffic on buses and memory channels.

One or more example embodiments provide methods, devices, and non-transitory computer-readable storage mediums that may reduce the amount of traffic on a memory channel during operations, such as garbage collection, on-chip buffered programming (OBP), etc.

At least one example embodiment provides a more efficient garbage collection process in which page data output from a source NAND device to a device controller is concurrently and/or simultaneously loaded to a buffer at a target NAND device on the same channel as the source NAND device. The device controller decodes errors in the read page data to obtain locations of the errors, and then transmits error locations for the identified errors in the read page data to the target NAND. Unlike conventional garbage collection processes, the device controller does not transmit the read data back to the target NAND device along with the locations of the errors. Since the read page data is not transmitted back to the target NAND device, the traffic on the memory channel is reduced relative to the conventional art. In response to receiving the error locations, the target NAND device corrects the errors in the buffered page data, and then writes the page data to a memory block at the target NAND device.

One or more example embodiments also provide storage devices to perform the more efficient garbage collection operation, and non-transitory computer-readable storage mediums storing computer executable instructions that, when executed, cause a processor to perform the more efficient garbage collection processes.

According to at least some example embodiments, an additional command may be used to support communicate between NAND device and device controller.

Since the algorithm is performed on a super-block, no further changes are needed for the FTL. A super-block is a group of blocks where each block is taken from a different NAND (or other memory) device in the memory system.

Example embodiments may also enable read-for-copy-back commands, which are not employed in conventional non-volatile memory because of additive write errors.

Example embodiments also provide a more efficient OBP operation, a storage device to perform the more efficient OBP operation, and a non-transitory computer-readable storage medium storing computer executable instructions that, when executed, cause a processor to perform the more efficient OBP operation.

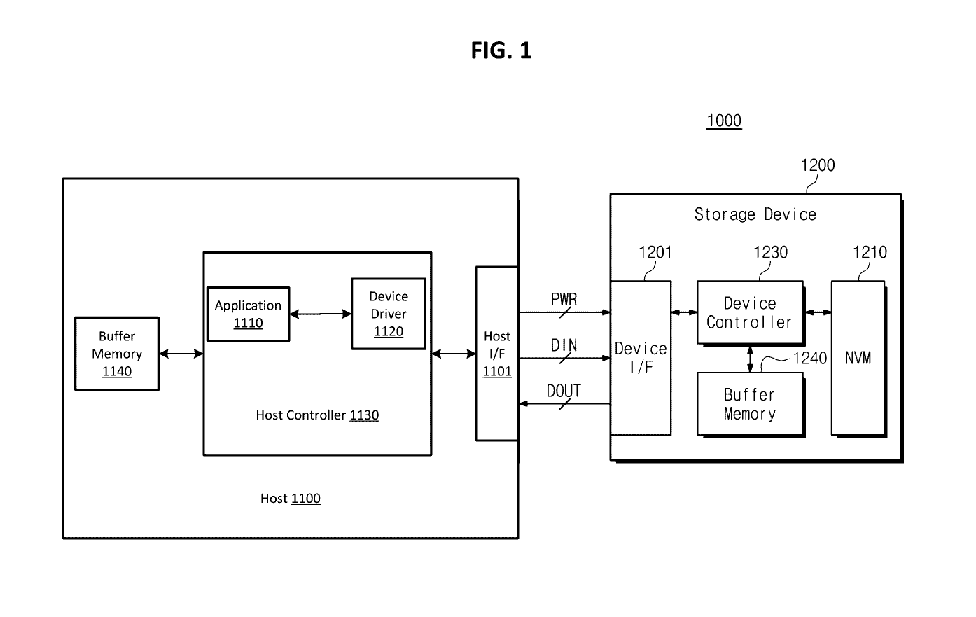

FIG. 1 is a block diagram schematically illustrating a storage system according to an example embodiment.

Referring to FIG. 1, the storage system 1000 includes a host 1100 and a storage device 1200. The host 1100 includes: a host interface 1101; a host controller 1130; and a buffer memory 1140. The storage device 1200 includes: a device interface 1201; a non-volatile memory (NVM) 1210; a device controller (also referred to as a memory controller) 1230; and a buffer memory 1240.

The storage device 1200 and the host 1100 are connected to one another through the interfaces 1101 and 1201. The host interface 1101 and the device interface 1201 may be standardized interfaces such as a Universal Flash Storage (UFS) interface, a serial advanced technology attachment (SATA) interface, a Small Computer Small Interface (SCSI), a serial attached SCSI (SAS), universal serial bus (USB) interface, etc. The host interface 1101 and the device interface 1201 are connected by data lines DIN and DOUT for exchanging data and/or signals, and by power lines PWR for providing power. In the example shown in FIG. 1, the host interface 1101 provides power to the device interface 1201 via the power line PWR.

The host controller 1130 receives data from, and sends commands (e.g., read and/or write) and/or data to, the storage device 1200 through the host interface 1101. The host controller 1130 includes an application 1110 and the device driver 1120. The application 1110 and/or the device driver 1120 may be implemented by hardware, software and/or firmware. The application 1110 may refer to one or more application programs executed by the host controller 1130 at the host 1100.

The device driver 1120 operates or controls devices attached to the host 1100 by providing a software interface to hardware devices, enabling operating systems and other host programs to access hardware functions without knowledge of precise details of the hardware being used.

The buffer memory 1140 may be used as a main memory and/or a cache memory of the host 1100. The buffer memory 1140 (e.g., synchronous random access memory (SRAM) and/or dynamic random access memory (DRAM)) may also be used as a driving memory to drive software such as the application 1110 and/or the device driver 1120.

Still referring to FIG. 1, as mentioned above, the storage device 1200 includes: a non-volatile memory (or memory device) 1210; a device controller (also referred to as a memory controller) 1230; and a buffer memory 1240. In this example, the storage device 1200 may be a data storage device based on a non-volatile memory, such as a solid state drive (SSD), a flash memory, a magnetic random access memory (MRAM), a phase change RAM (PRAM), a ferroelectric RAM (FeRAM), etc.

In one example, the non-volatile memory may be a two-dimensional (2D) or three dimensional (3D) memory array. A 3D memory array is monolithically formed in physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

The 3D memory array includes vertical NAND strings that are vertically oriented such that at least one memory cell is located over another memory cell. The at least one memory cell may comprise a charge trap layer.

The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and U.S. Patent Application Publication No. 2011/0233648.

The device controller 1230 controls an overall operation of the non-volatile memory 1210 including, for example, write operations, read operations, erase operations, maintenance operations (including, e.g., garbage collection), encoding/decoding, error correction, etc. The device controller 1230 exchanges data, address information and/or error location information with the non-volatile memory 1210 and/or the buffer memory 1240 through an address and/or data bus.

Still referring to FIG. 1, the buffer memory 1240 temporarily stores data to be stored in the non-volatile memory 1210 and/or data read from the non-volatile memory 1210. The buffer memory 1240 may be implemented by a volatile and/or non-volatile memory (e.g., synchronous random access memory (SRAM) and/or dynamic random access memory (DRAM)).

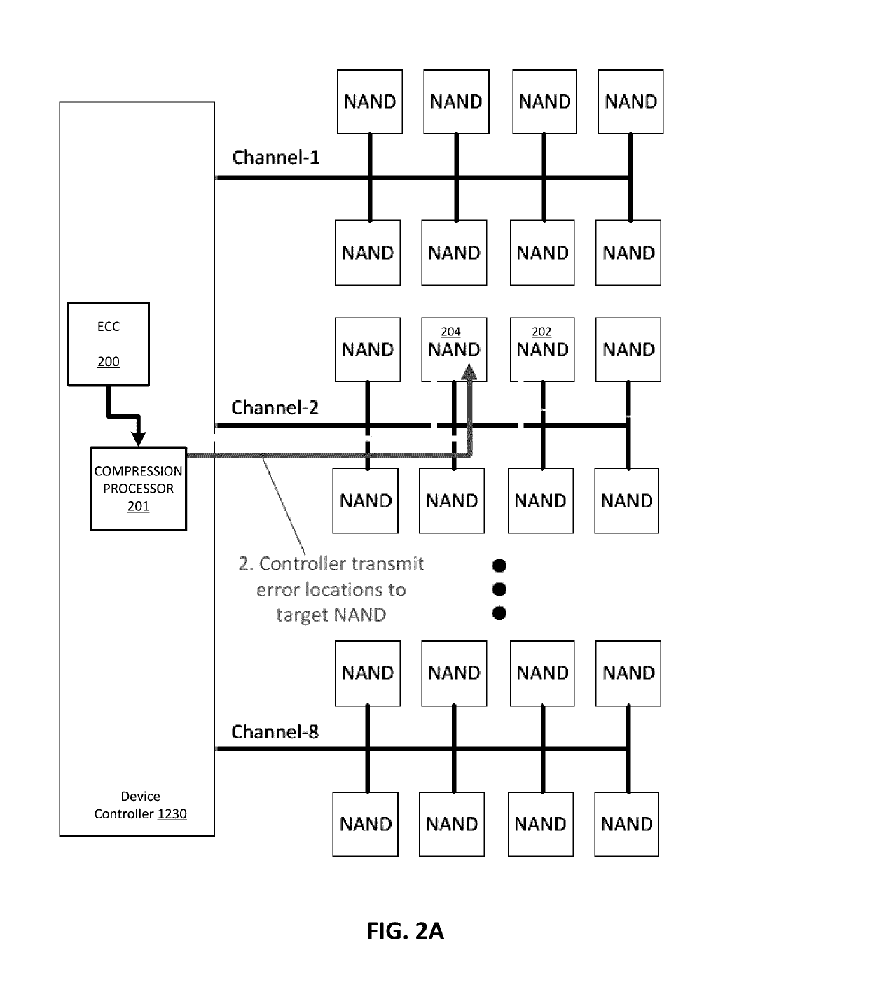

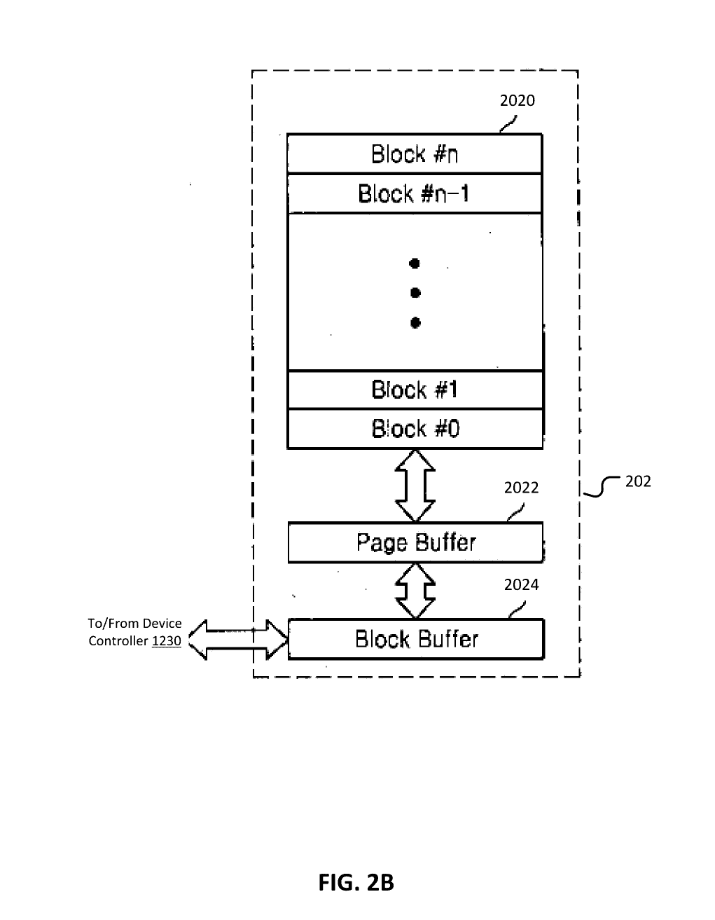

More detailed discussion of the device controller 1230, the buffer memory 1240 and the non-volatile memory 1210, including additional functionality of these components, will be provided later with regard to FIGS. 2A through 5.

FIG. 2A is a block diagram illustrating an example embodiment of a portion of the storage device shown in FIG. 1 in more detail. FIG. 2B is a block diagram illustrating an example embodiment of the NAND device 202 in more detail. Although not shown in FIG. 2B, the NAND device 204 may be the same or substantially the same as the NAND device 202.

Referring to FIG. 2A, the device controller 1230 includes an error correction coding (ECC) circuit (or, alternatively, processor) 200 and a compression processor 201. The ECC circuit 200 and the compression processor 201 are operatively coupled to one another. In at least one example embodiment, the ECC circuit 200 and the compression processor 201 may be implemented on a main processor at the device controller 1230. Alternatively, the ECC circuit 200 and the compression processor 201 may be implemented on separate processors at the device controller 1230.

Still referring to FIG. 2A, the non-volatile memory 1210 includes a plurality of sets of NAND devices (also referred to as non-volatile memory devices). Each NAND device may be, or include, one or more NAND chips or NAND dies.

Each set of NAND devices is connected to one of a plurality of NAND channels (also referred to as memory channels) Channel-1, Channel-2, . . . , Channel-8. Although only three sets of NAND devices and three NAND channels are shown in FIG. 2A, the non-volatile memory 1210 may include any number of NAND devices.

Referring to FIG. 2B, the NAND device 202 includes: a memory cell array 2020; a page buffer 2022; and a memory block buffer 2024. The memory cell array 2020 includes a plurality of memory blocks Block#0, Block#1, . . . Block#i, . . . , Block#n-1, and Block#n. Each of the memory blocks Block#0 through Block#n includes a plurality of memory cells. Data is stored in each of the memory blocks Block#0 through Block#n in pages, and each of the memory blocks Block#0 through Block#n may store a plurality of pages of data.

The memory block buffer 2024 buffers a block of data received from the device controller 1230. The memory block buffer 2024 sequentially outputs the pages of the data to the page buffer 2022. The page buffer 2022 then outputs a page of the program data to one of the memory blocks Block#0 through Block#n to program the page data to a page of the memory block.

The memory block buffer 2024 stores the block of data until the block of data is completely stored in the memory blocks Block#0 through Block#n of the NAND device 202.

When page data is read from a memory block of the memory cell array 2020, the read page data may be temporarily buffered in the page buffer 2022 and then output to, for example, the device controller 1230. Although the memory block buffer 2024 is included in the NAND device 202 illustrated in FIG. 2B, the memory block buffer 2024 may be included in the device controller 1230 or the memory block buffer 2024 may be separately implemented between the device controller 1230 and the NAND device 202.

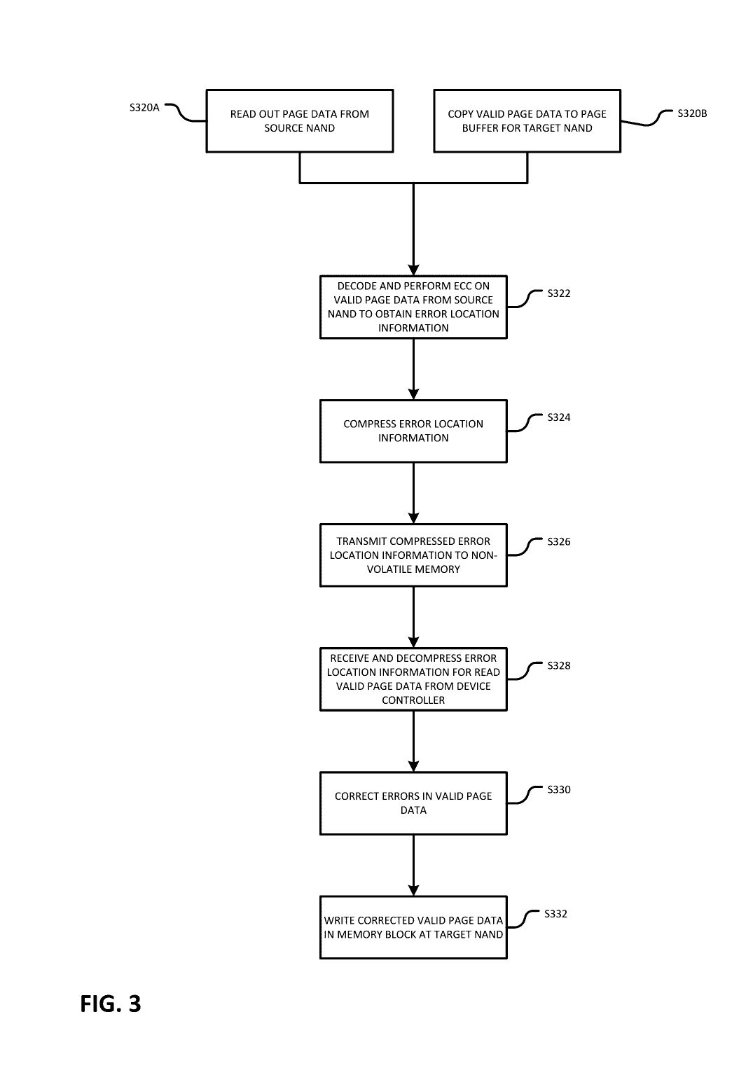

Example operation of the device controller 1230 and the non-volatile memory 1210 during an example embodiment of a garbage collection operation will be discussed in more detail below with regard to FIG. 3.

For example purposes, a case in which valid page data in an i-th source memory block among Block#0 through Block#n in the NAND device (also referred to as a source NAND device) 202 is copied to a j-th (e.g., erased) memory block in the NAND device 204 (also referred to as a target NAND device) on the same SSD channel Channel-2 will be described. If the target memory block requires erasing prior to copying the page data, the erase operation may be performed independently using any suitable well-known algorithm. Although example embodiments will be described with regard to NAND device 202 and NAND device 204 shown in FIGS. 2A and 2B, the same or substantially the same operations may be performed for each NAND device.

In alternative example embodiments, the j-th target memory block may be located on the same NAND device 202 as the i-th source memory block. In this example, the read page data from the i-th source memory block may be stored at an internal page buffer (not shown) until the error locations are received from the device controller 1230. The page data may then be written to the j-th target memory block.

FIG. 3 is a flow chart illustrating an example embodiment of a garbage collection operation. The method shown in FIG. 3 will be described with regard to the device controller 1230 and the non-volatile memory 1210 shown in FIGS. 2A and 2B.

Referring to FIG. 3, at step S320A, the device controller 1230 reads valid page data from the i-th source memory block at the source NAND device 202. In one example, the device controller 1230 reads the valid page data from the i-th source memory block at the source NAND device 202 by applying a conventional read command to the source NAND device 202 while the chip enable (CE) signal for the NAND device 202 is enabled.

Concurrently and/or simultaneously with the reading out of the valid page data from the i-th source memory block at the NAND device 202, at S320B the non-volatile memory 1210 begins a copy-back operation to copy the page data from the i-th source memory block of the source NAND device 202 to the target NAND device 204. In so doing, the non-volatile memory 1210 copies the valid page data from the i-th source memory block at the source NAND device 202 to a buffer (e.g., a page or block buffer shown in FIG. 2B) at the target NAND device 204. The valid page data from the i-th memory block at the source NAND device 202 is held in the buffer at the target NAND device 204 until receipt of the compressed error location information at 5328, which is discussed in more detail later.

Since device controller signals are shared among NAND devices sharing the same channel, an additional NAND command may be used to copy the page data from the i-th source memory block to the target NAND device 204 simultaneously and/or concurrently while the valid page data is read out by the device controller 1230. As discussed above, a conventional read command may be used to read out the valid page data from the i-th source memory block at the source NAND device 202 to the device controller 1230 while the chip enable (CE) signal for the source NAND device 202 is enabled. To concurrently and/or simultaneously copy the valid page data from the i-th source memory block to the target NAND device 204, the CE for the target NAND device 204 may be enabled, and a write command, which is different from the conventional write command, may be applied to the target NAND device 204. This write command may be referred to as a “GC write” and may have a signal set 8110h. The GC write command may differ from a conventional write command in that data is loaded for programming in response to a REb signal, rather than a WEb signal, and after receiving the valid page data from the source NAND device 202, the target NAND device 204 expects an additional transmission from the device controller 1230 (including the error location information) before programming the valid page data to the target NAND device 204. The programming of the page data to the target NAND device 204 is initiated in response to setting of a WEb flag.

Still referring to FIG. 3, upon receipt of the valid page data from the NAND device 202 by the device controller 1230, at S322 the ECC circuit 200 decodes the valid page data, and performs an ECC operation on the valid page data to identify errors in the valid page data, and locations of the identified errors in the valid page data. The ECC circuit 200 may perform the ECC operation on the received valid page data from the NAND device 202 in any well-known manner. The location of the errors may be referred to herein as error location information and may refer to the locations of error bits in the valid page data. The ECC circuit 200 then outputs the error location information for the valid page data to the compression processor 201.

At step S324, the compression processor 201 compresses the error location information received from the ECC circuit 200 to generate compressed error location information. The compression processor 201 may compress the error location information in any well-known manner. For example, the compression processor 201 may compress the error location information using Tunstall coding, Huffman coding, or any other suitable compression algorithm.

At S326, the device controller 1230 transmits the compressed error location information to the target NAND device 204 via the NAND channel Channel-2. In this example, the device controller 1230 does not transmit the valid page data from the source NAND device 202 to the target NAND device 204 as is the case with the conventional art. Rather, the device controller 1230 transmits only the compressed error location information to the target NAND device 204, without the valid page data, to inform the target NAND device 204 of the locations of errors in the valid page data read from the i-th source memory block of the source NAND device 202.

At S328, the non-volatile memory 1210 receives and decompresses the compressed error location information from the device controller 1230 to obtain the locations of errors in the valid page data read from the i-th source memory block at the source NAND device 202. The non-volatile memory 1210 may decompress the compressed error location information in any well-known manner.

At S330 the non-volatile memory 1210 corrects the errors in the valid page data in the buffer at the target NAND device 204 based on the error locations obtained at S328. In one example, at S330 the non-volatile memory 1210 flips or inverts the data bits of the valid page data in the buffer at the bit locations obtained at S328. The non-volatile memory 1210 may adjust the bits of the valid page data at the locations obtained at S328 in any well-known manner.

After correcting errors in the valid page data in the buffer at the target NAND device 204, at S332 the non-volatile memory 1210 writes the error corrected valid page data from the i-th source memory block of the source NAND device 202 to the j-th memory block of the target NAND device 204. As mentioned briefly above, the programming of the error corrected valid page data to the target NAND device 204 may be initiated in response to setting of a WEb flag by the device controller 1230.

The operations discussed above with regard to FIG. 3 may be performed iteratively, and separate iterations of the operations discussed above with regard to the example embodiment shown in FIG. 3 may overlap. In one example, concurrently with the writing of the error corrected page data to the target NAND device 204 at S332, the device controller 1230 may read out page data from another memory block of a NAND device at S320A and initiate the copy-back operation at S320B. The process may then be repeated for different NAND devices.

Example embodiments also provide methods for more efficient on-chip buffered program (OBP) operations, storage devices for performing more efficient OBP operations, and non-transitory computer-readable storage mediums storing computer executable instructions that when executed by computer cause the computer to perform methods for more efficient on-chip buffered program (OBP) operations.

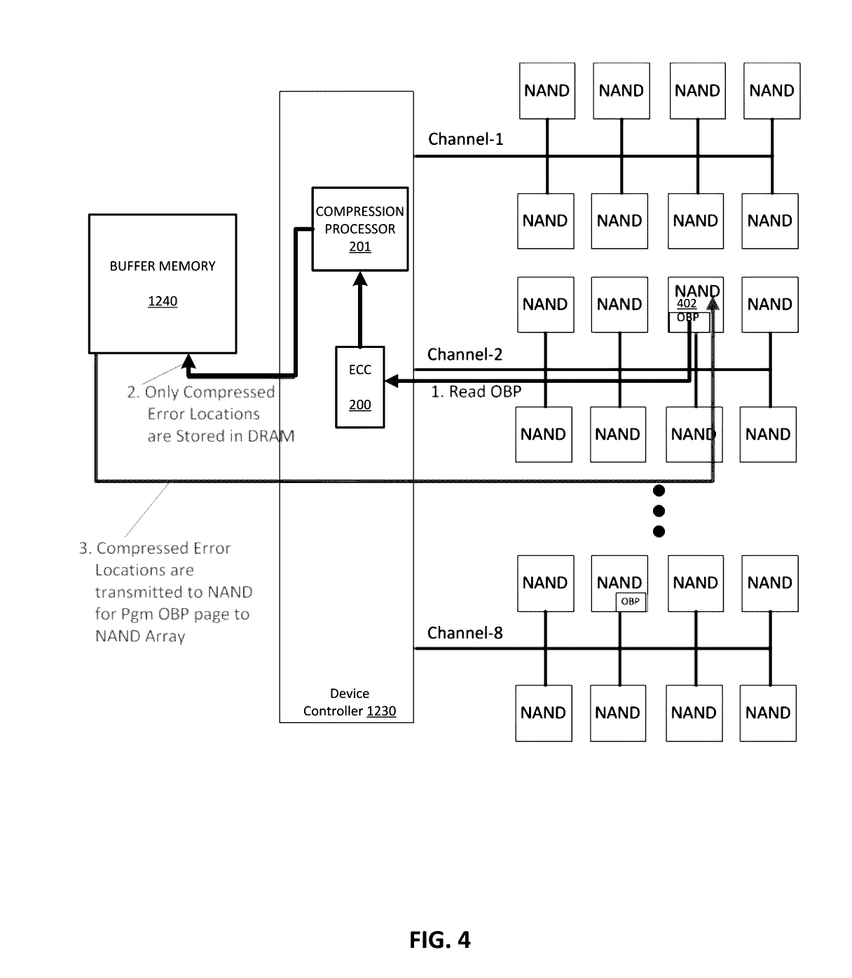

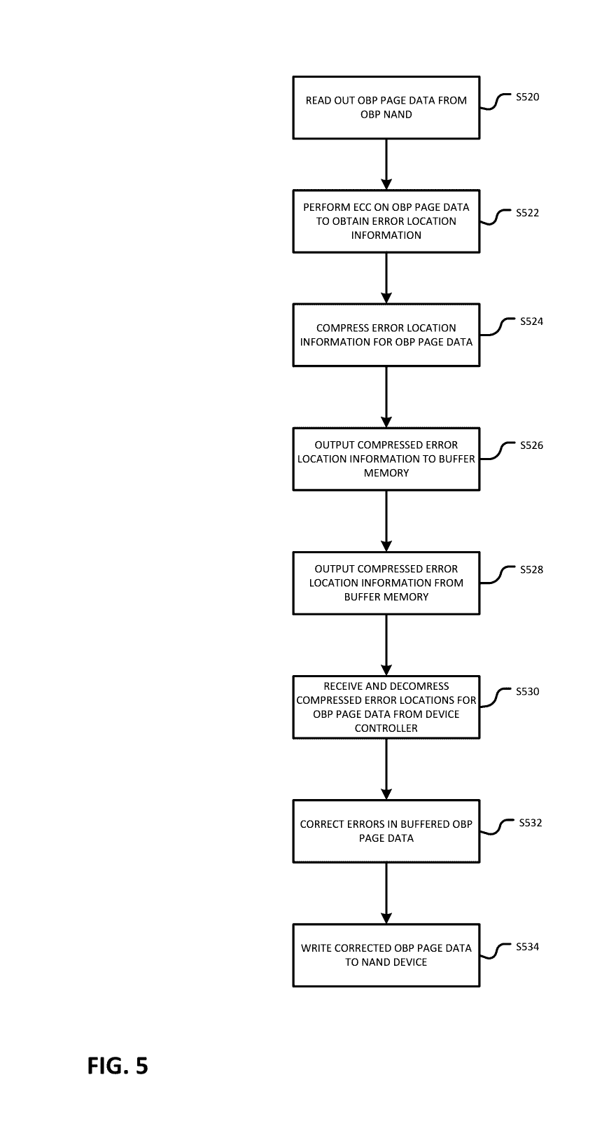

In an OBP operation, page data to be programmed to a memory block of a NAND device is temporarily stored in a buffer memory (e.g., a buffer memory for the memory controller or a storage space at a NAND device), and a program operation for the buffered page data is carried out later. A more detailed discussion of an example embodiment of an OBP operation will be discussed in more detail below with regard to FIGS. 4 and 5.

FIG. 4 is a block diagram illustrating another example embodiment of a portion of the storage device shown in FIG. 1 in more detail. FIG. 4 is similar to FIG. 2A, but further illustrates the buffer memory 1240 communicatively coupled to the device controller 1230. Moreover, in the example embodiment shown in FIG. 4 the NAND devices are the same or substantially the same as the NAND devices shown in FIG. 2A, except that the set of NAND devices coupled to the NAND channel Channel-2 includes a NAND device 402 that buffers and then stores OBP page data during an OBP operation. Example operation of the example embodiment shown in FIG. 4 will be described in more detail below with regard to FIG. 5.

FIG. 5 is a flow chart illustrating an OBP operation according to an example embodiment. The OBP operation shown in FIG. 5 will be discussed with regard to the portion of the storage device shown in FIG. 4.

Referring to FIGS. 4 and 5, at S520 the device controller 1230 reads out OBP page data from the NAND device 402. In one example, the device controller 1230 reads out the OBP page data from the page buffer at the NAND device 402.

Upon receipt of the OBP page data from the NAND device 402 at the device controller 1230, at S522 the ECC circuit 200 decodes and performs an ECC operation on the received OBP page data to identify errors and locations of errors in the received OBP page data. The ECC circuit 200 may perform the ECC operation on the received OBP page data in the same or substantially the same manner as discussed above with regard to S322 in FIG. 3. As with the example embodiment discussed above with regard to FIG. 3, the locations of the errors in the OBP page data may be referred to as error location information and may refer to the locations of error bits in the OBP page data. The ECC circuit 200 outputs the error location information for the OBP page data to the compression processor 201.

At step S524, the compression processor 201 compresses the error location information received from the ECC circuit 200 to generate compressed error location information. The compression processor 201 may compress the error location information in the same or substantially the same manner as discussed above with regard to S324 in FIG. 3.

Still referring to FIGS. 4 and 5, at S526 the device controller 1230 outputs the compressed error location information to the buffer memory 1240. In this example, the device controller 1230 does not output the OBP page data from the NAND device 402 to the buffer memory 1240. Rather, the device controller 1230 outputs only the compressed error location information to the buffer memory 1240. Thus, the amount of buffer memory required during an OBP program operation may be reduced relative to conventional OBP operations.

After buffering the compressed error location information, at S528 the buffer memory 1240 outputs the compressed error location information to the non-volatile memory 1210. In this case, the buffer memory 1240 outputs only the compressed error location information to the non-volatile memory 1210. In one example, the buffer memory 1240 outputs the compressed error location information to the non-volatile memory 1210 in response to a read request from one of the device controller 1230 and the non-volatile memory 1210. In one example, the compressed error locations may be output from the buffer memory 1240 along with the write-back of the page with which the compressed error locations are associated.

At S530, the non-volatile memory 1210 receives and decompresses the compressed error location information from the device controller 1230 to obtain the locations of errors in the OBP page data stored in the page buffer at the NAND device 402. As with S328 in FIG. 3, the non-volatile memory 1210 may decompress the compressed error location information in any well-known manner.

At S532, the non-volatile memory 1210 corrects the errors in the OBP page data stored in the page buffer based on the error locations obtained at S530. In one example, at S532 the non-volatile memory 1210 flips or inverts the data bits of the OBP page data at the bit locations identified at S530. The non-volatile memory 1210 may adjust the bits of the valid page data at the locations identified in the compressed error location information in any well-known manner.

After correcting the errors in the OBP page data in the page buffer, at S534 the corrected OBP page data is written or programmed to a memory block of the NAND device 402 to complete the OBP program operation.

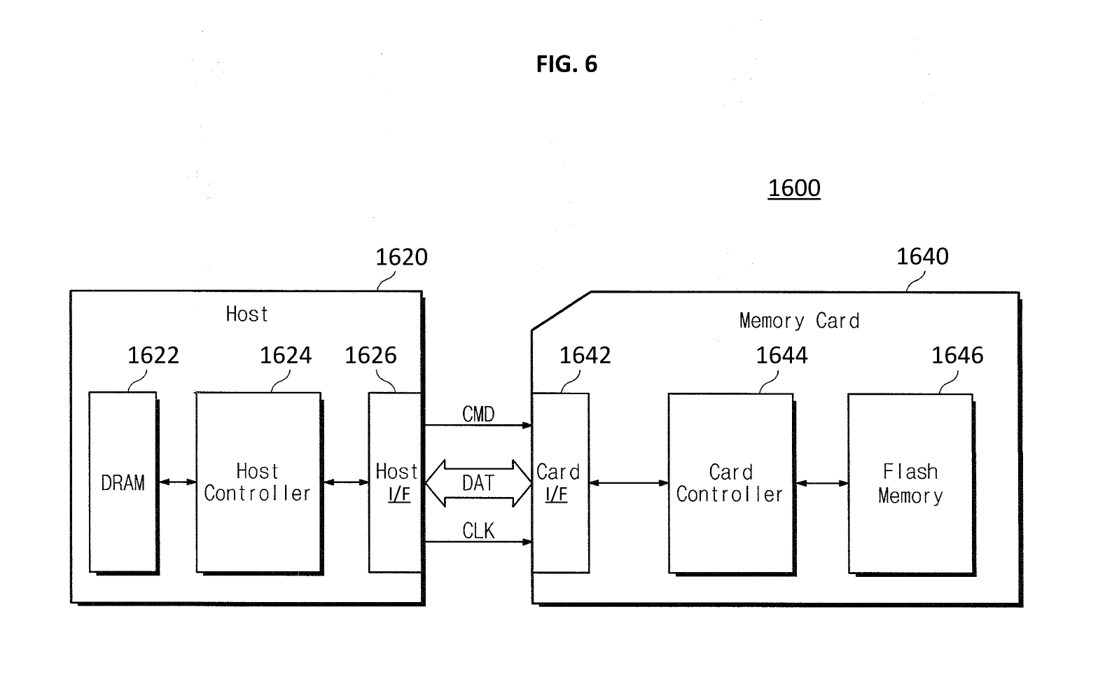

FIG. 6 is a block diagram illustrating a memory card system including a storage device according to an example embodiment.

Referring to FIG. 6, a memory card system 1600 includes a host 1620 and a memory card 1640. The host 1620 includes a host controller 1624, a host interface 1626, and a DRAM 1622.

The host 1620 writes data to the memory card 1640 and/or reads data from the memory card 1640. The host controller 1624 sends a command CMD (e.g., a write command), a clock signal CLK generated from a clock generator (not shown) in the host 1620, and data DAT to the memory card 1640 via the host interface 1626. The DRAM 1622 may be a main memory of the host 1620.

The memory card 1640 includes a card interface 1642, a card controller 1644, and a flash memory 1646. The card controller 1644 stores data at the flash memory 1646 in response to a command input via the card interface 1642. The data may be stored in synchronization with the clock signal CLK generated from the clock generator (not shown) in the card controller 1644. The flash memory 1646 stores data transferred from the host 1620. The flash memory 1646 may operate in accordance with example embodiments discussed above with regard to FIGS. 2A through 5 to perform more efficient garbage collection operations and/or OBP operations. The card controller 1644 may include, or be implemented as, the device controller 1230 discussed above with regard to FIGS. 2A through 5. Accordingly, the memory card 1644 may operate in accordance with example embodiments to perform more efficient garbage collection operations and/or OBP operations.

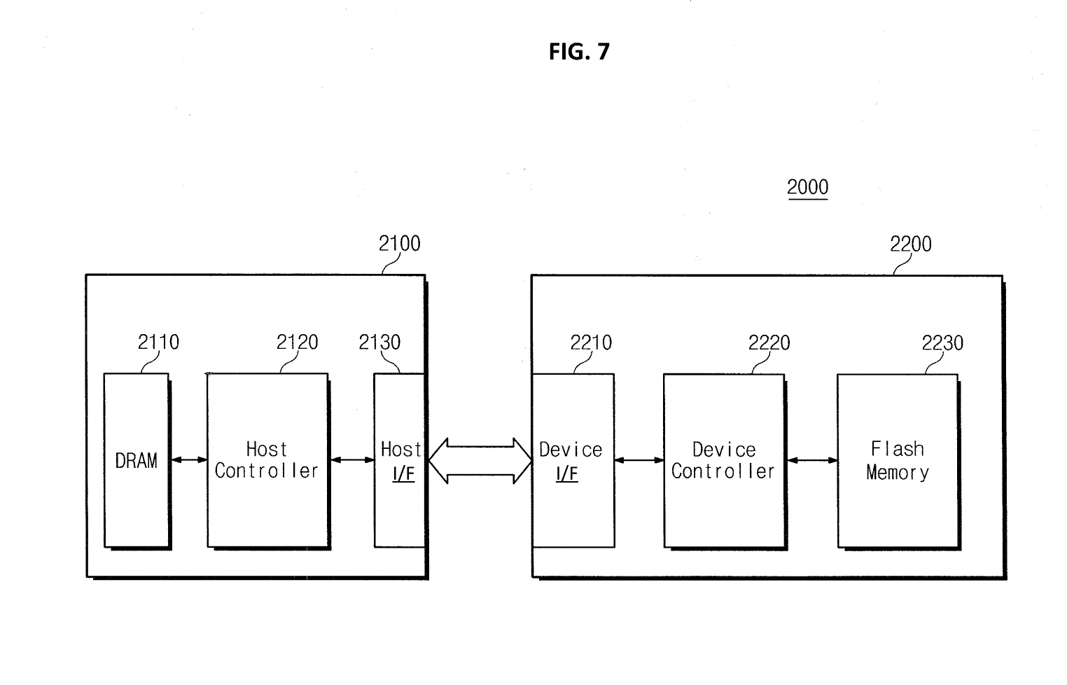

FIG. 7 is a block diagram illustrating a Universal Flash Storage (UFS) system in which a non-volatile memory device according to an example embodiment may be implemented.

Referring to FIG. 7, a UFS system 2000 includes a UFS host 2100 and a UFS device 2200. The UFS host 2100 includes a host controller 2120, a host interface 2130, and a DRAM 2110.

The UFS host 2100 writes data in the UFS device 2200 and/or reads data from the UFS device 2200. The DRAM 2110 may be a main memory of the UFS host 2100. The UFS host 2100 communicates with the UFS device 2200 via the host interface 2130 and a device interface 2210 of the UFS device 2200.

The UFS device 2200 includes the device interface 2210, a device controller 2220, and a flash memory 2230. The device controller 2220 stores data at the flash memory 2230 in response to a command input via the device interface 2210. The flash memory 2230 stores data transferred from the UFS host 2100.

The UFS device 2200 may operate in accordance with example embodiments to perform more efficient garbage collection operations and/or OBP operations.

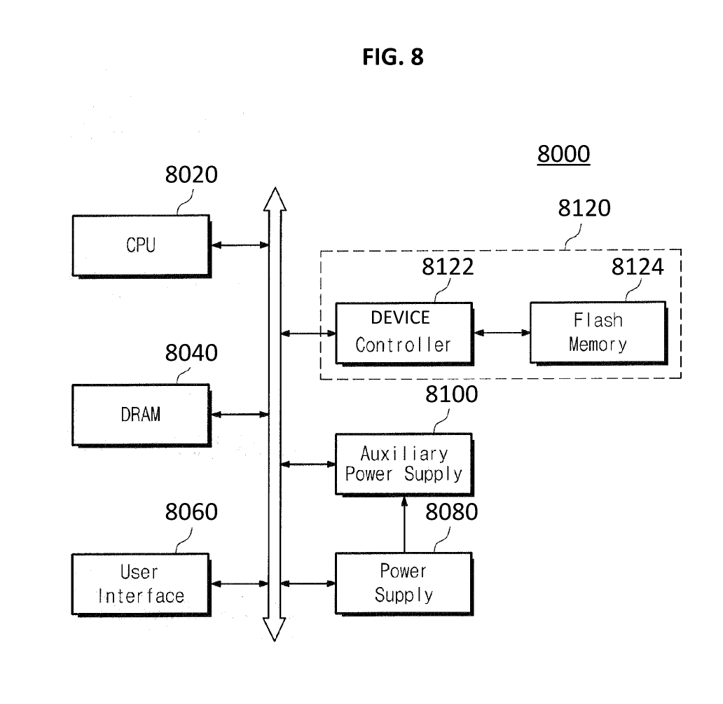

FIG. 8 is a block diagram illustrating an electronic device including a memory device according to an example embodiment. Herein, an electronic device may be a personal computer or a handheld electronic device such as a notebook computer, a cellular phone, a personal digital assistant (PDA), a camera, or the like.

Referring to FIG. 8, the electronic device 8000 includes: a memory device 8120; a power supply device 8080; an auxiliary power supply 8100; a CPU 8020; a DRAM 8040; and a user interface 8060. The memory device 8120 includes a flash memory 8124 and a device controller 8122. The memory device 8120 may be built in the electronic device 8000.

The memory device 8120 may operate in accordance with example embodiments to perform more efficient garbage collection operations and/or OBP operations.

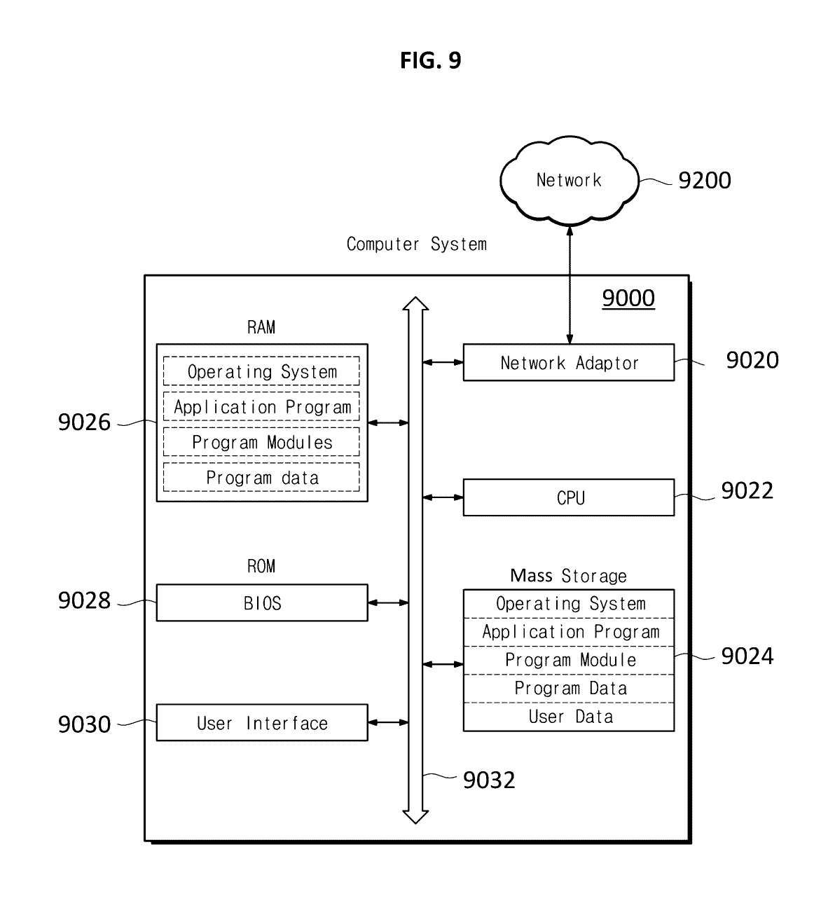

FIG. 9 is a block diagram schematically illustrating a computing system including a storage device according to an example embodiment.

Referring to FIG. 9, a computing system 9000 includes: a network adaptor 9020; a central processing unit (CPU) 9022; a mass storage device 9024; a RAM 9026; a ROM 9028; and a user interface 9030. The components of the computing system 9000 are connected by a system bus 9032.

The network adaptor 9020 provides an interface between the computing system 9000 and external networks 9200. The CPU 9022 controls an overall operation for driving an operating system and an application program which are resident on the RAM 9026. The mass storage device 9024 stores data needed for the computing system 9000. For example, the mass storage device 9024 may store an operating system for driving the computing system 9000, an application program, various program modules, program data, user data, etc.

The RAM 9026 is used as a working memory of the computing system 9000. Upon booting, the operating system, the application program, the various program modules, and program data needed to drive programs and various program modules read out from the mass storage device 9024 may be loaded into the RAM 9026. The ROM 9028 stores a basic input/output system (BIOS), which is activated before the operating system is driven upon booting. Information exchange between the computing system 9000 and a user may be made via the user interface 9030.

In addition, the computing system 9000 may further include a battery, a modem, and the like. Although not shown, the computing system 9000 may further include an application chipset, a camera image processor (CIS), a mobile DRAM, and the like.

The mass storage device 9024 may operate in accordance with example embodiments to perform more efficient garbage collection operations and/or OBP operations.

According to one or more example embodiments, the mass storage device 9024 may be implemented by a solid state drive, a multimedia card (MMC), a secure digital (SD) card, a micro SD card, a memory stick, an ID card, a PCMCIA card, a chip card, an USB card, a smart card, a compact flash (CF) card, etc.

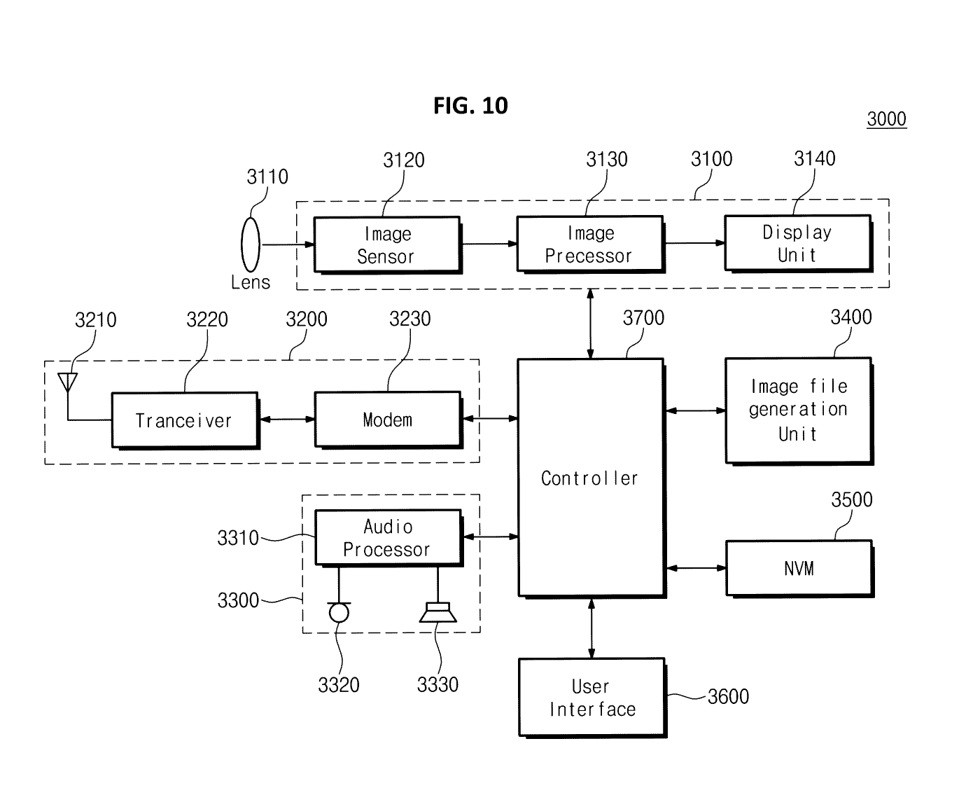

FIG. 10 is a block diagram schematically illustrating a handheld terminal according to an example embodiment.

Referring to FIG. 10, a handheld terminal 3000 includes: an image processing circuit 3100; a wireless transceiver circuit 3200; an audio processing circuit 3300; an image file generating circuit 3400; a non-volatile memory device 3500; a user interface 3600; and a controller 3700.

The image processing circuit 3100 includes: a lens 3110; an image sensor 3120; an image processor 3130; and a display unit 3140. The wireless transceiver circuit 3200 includes: an antenna 3210; a transceiver 3220; and a modem 3230. The audio processing circuit 3300 includes: an audio processor 3310; a microphone 3320; and a speaker 3330.

The non-volatile memory device 3500 may operate in accordance with example embodiments to perform more efficient garbage collection operations and/or OBP operations. The non-volatile memory device 3500 shown in FIG. 10 may be one of a memory system, a memory card, an SSD, an eMMC, etc.

Nonvolatile memory devices and/or memory controllers according to example embodiments of inventive concepts may be packed by according to various types of packages such as Package on Package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), and the like.

The foregoing description of example embodiments has been provided for purposes of illustration and description. It is not intended to be exhaustive or limiting. Individual elements or features of a particular example embodiment are generally not limited to that particular example embodiment. Rather, where applicable, individual elements or features are interchangeable and may be used in a selected embodiment, even if not specifically shown or described. The same may also be varied in many ways. All such modifications are intended to be included within the scope of this disclosure.

1. A memory device controller, comprising:
an error correction processor configured to obtain error location information for page data received from a source memory block over a memory channel; and
a compression processor configured to compress the obtained error location information, and to output the compressed error location information to a target memory block without the received page data over the same memory channel.

2. The memory device controller of claim 1, wherein the compression processor is configured to output only the compressed error location information to the target memory block.

3. The memory device controller of claim 1, wherein the error correction processor is further configured to perform error correction coding on the received page data to obtain the error location information for the page data, the error location information including locations of errors in the received page data.

4. The memory device controller of claim 1, wherein the source memory block and the target memory block are located at a same non-volatile memory device connected to the memory channel.

5. The memory device controller of claim 1, wherein the received page data is valid page data read from the source memory block during a garbage collection operation.

6. The memory device controller of claim 1, wherein
the received page data is on-chip buffered program (OBP) data; and
the compressed error location information is buffered prior to being output to the target memory block.

7. The memory device controller of claim 6, wherein the source memory block and the target memory block are located at a same non-volatile memory device connected to the memory channel.

8. A storage device comprising:
a source non-volatile memory device connected to a memory channel, the source non-volatile memory device including a source memory block; and
a memory device controller configured to communicate with the source non-volatile memory device via the memory channel, the memory device controller including,
an error correction processor configured to obtain error location information for page data received from the source memory block over the memory channel; and
a compression processor configured to compress the obtained error location information, and output the compressed error location information to a target memory block without the page data over the same memory channel.

9. The storage device of claim 8, wherein the page data is valid page data read from the source memory block during a garbage collection operation.

10. The storage device of claim 8, wherein
the page data is on-chip buffered program (OBP) data; and
the compressed error location information is buffered prior to being output to the target memory block.

11. A storage device comprising:
a first non-volatile memory device connected to a memory channel, the first non-volatile memory device including a plurality of memory blocks and a page buffer, and the first non-volatile memory device being configured to
buffer page data read from a source memory block,
correct errors in the buffered page data in response to receiving error location information from a memory device controller via the memory channel, and without receiving the page data from the memory device controller, and
write the error corrected page data to a target memory block among the plurality of memory blocks of the first non-volatile memory device.

12. The storage device of claim 11, wherein
at least one of the source and the target memory blocks are in the form of a three-dimensional memory array.

13. The storage device of claim 12, wherein the three dimensional memory array includes a plurality of memory cells, each of the plurality of memory cells including a charge trap layer.

14. The storage device of claim 11, wherein the first non-volatile memory device is a NAND device.

15. The storage device of claim 11, wherein the first non-volatile memory device is configured to correct errors in the buffered page data in response to receiving only the compressed error location information from the memory device controller.

16. The storage device of claim 11, wherein the first non-volatile memory device further includes the source memory block.

17. The storage device of claim 11, wherein the page data is one of on-chip buffered program (OBP) data and valid page data read from the source memory block during a garbage collection operation.

18-20. (canceled)
